(19) United States
(12) Patent Application Publication
(10) Pub. No.: US 2026/0191095 A1
(43) Pub. Date: Jul. 2, 2026

(54) ULTRA HIGH BANDWIDTH MEMORY WITH BACKEND TRANSISTORS

(71) Applicant: Intel Corporation, Santa Clara, CA (US)

(72) Inventors: Abhishek Anil SHARMA, Portland, OR (US); Anand IYER, Saratoga, CA (US); Prashant MAJHI, San Jose, CA (US); Nitin A. DESHPANDE, Chandler, AZ (US)

(21) Appl. No.: 19/001,921

(22) Filed: Dec. 26, 2024

(51) Int. Cl. H01L 25/07; H01L 21/66; H10B 80/00

(52) U.S. Cl. CPC H10W 90/00; H10B 80/00; H10P 74/27; H10W 90/297

(57) ABSTRACT

Embodiments disclosed herein include ultra high bandwidth memory (HBM) with backend transistors. In an example, a memory structure includes a package substrate. A base die is coupled to the package substrate and a memory die stack is coupled to the base die, or a memory die stack is coupled to the package substrate. Each memory die in the die stack includes one transistor one capacitor (1T1C) backend dynamic random access memory (DRAM).

### BACKGROUND

High bandwidth memory (HBM) is a computer memory interface for 3D-stacked synchronous dynamic random-access memory (SDRAM). It is used in conjunction with high-performance graphics accelerators, network devices, high-performance datacenter AI ASICs, as on-package cache in CPUs and on-package RAM in CPUs, and FPGAs and in some supercomputers.

However, improvements are needed in the field of high bandwidth memory.

### BRIEF DESCRIPTION OF THE DRAWINGS

FIG. 1A illustrates a cross-sectional view of a package including a high bandwidth memory (HBM), in accordance with an embodiment of the present disclosure.

FIG. 1B illustrates an angled view of a high bandwidth memory (HBM) die stack, in accordance with an embodiment of the present disclosure.

FIGS. 1C and 1D illustrate plan views of a memory die 120 and base die 130 for a high bandwidth memory (HBM) die stack, in accordance with an embodiment of the present disclosure.

FIG. 1E illustrates a plan view of a memory die for a high bandwidth memory (HBM) die stack, in accordance with another embodiment of the present disclosure.

FIG. 1F illustrates a cross-sectional view of a die stack and an associated exploded view, in accordance with an embodiment of the present disclosure.

FIG. 1G is a schematic of a basic building block for ultra high bandwidth memory, in accordance with an embodiment of the present disclosure.

FIG. 1H is a schematic of channel organization for ultra high bandwidth memory, in accordance with an embodiment of the present disclosure.

FIG. 2 is a cross-sectional illustration of a memory on package (MoP) architecture where the memory die stacks are provided on a package substrate that is connected to the main package substrate, in accordance with an embodiment of the present disclosure.

FIG. 3 is a plan view illustration of a MoP architecture with a mold layer over and around the memory die stacks and an opening in the mold layer to accommodate a die module, in accordance with an embodiment of the present disclosure.

FIG. 4 is a cross-sectional illustration of the package substrate with memory die stacks that are embedded in the mold layer, in accordance with an embodiment of the present disclosure.

FIG. 5 illustrates a cross-sectional view of a system including a reversed overhang memory on package structure, in accordance with an embodiment of the present disclosure.

FIG. 6 illustrates a cross-sectional view of a system including a reversed overhang memory on package structure, in accordance with an embodiment of the present disclosure.

FIG. 7 is a schematic of a computing device built in accordance with an embodiment.

### EMBODIMENTS OF THE PRESENT DISCLOSURE

Described herein are memory architectures that include memory stacks, in accordance with various embodiments. In the following description, various aspects of the illustrative implementations will be described using terms commonly employed by those skilled in the art to convey the substance of their work to others skilled in the art. However, it will be apparent to those skilled in the art that the present disclosure may be practiced with only some of the described aspects. For purposes of explanation, specific numbers, materials and configurations are set forth in order to provide a thorough understanding of the illustrative implementations. However, it will be apparent to one skilled in the art that the present disclosure may be practiced without the specific details. In other instances, well-known features are omitted or simplified in order not to obscure the illustrative implementations.

Various operations will be described as multiple discrete operations, in turn, in a manner that is most helpful in understanding the present disclosure, however, the order of description should not be construed to imply that these operations are necessarily order dependent. In particular, these operations need not be performed in the order of presentation.

Embodiments are directed to ultra high bandwidth memory (HBM) with backend transistors.

To provide context, state-of-the-art approaches for high bandwidth memory (HBM) can include use of single die one-transistor one-capacitor (1T1C) memory.

In accordance with embodiments described herein, an approach involves the use of a stack of N memory dies containing 1T1C backend DRAM, through silicon via (TSV) gutters and both-sided high bandwidth interconnect (HBI) connections. In an embodiment, built-in self-test (BIST), redundancy, TSVs and high speed universal chiplet interconnect express (UCIe) connections are included to funnel out the data from and XBM construct.

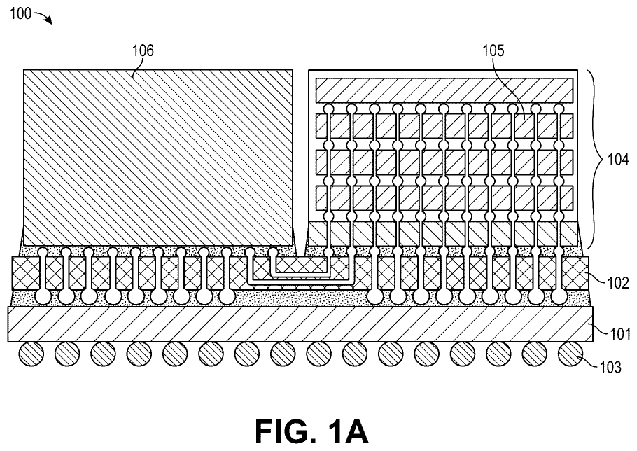

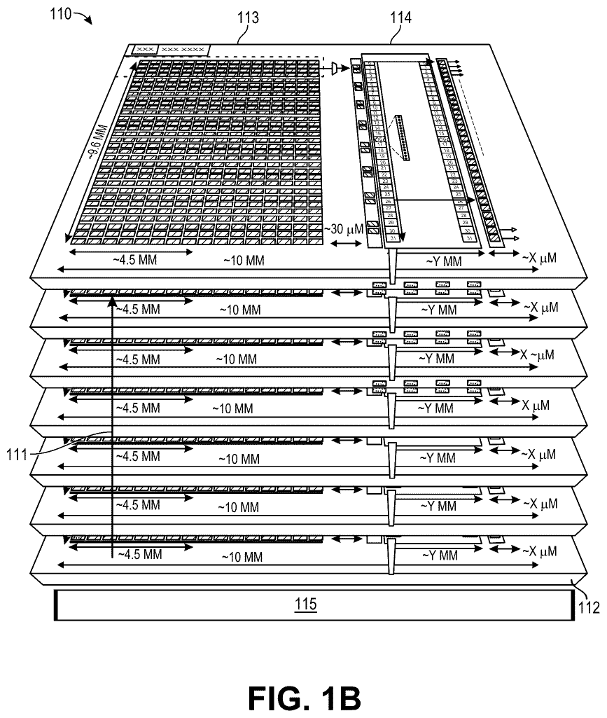

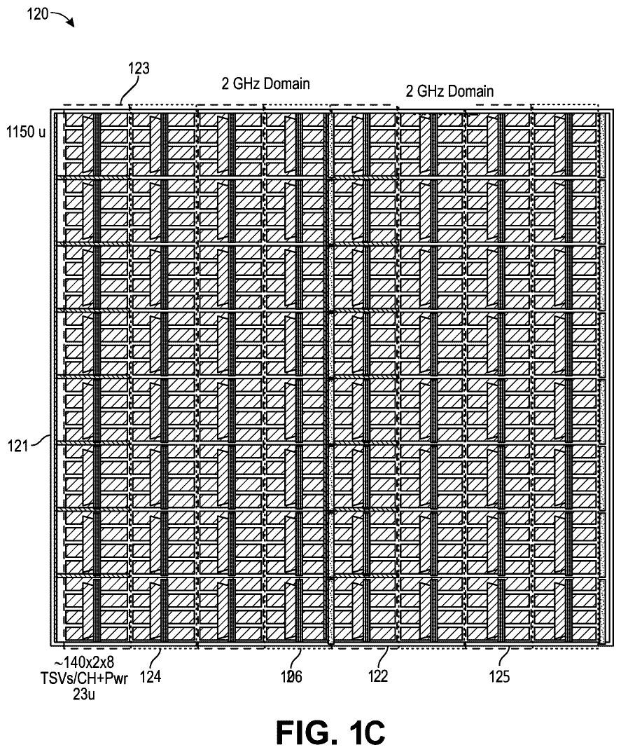

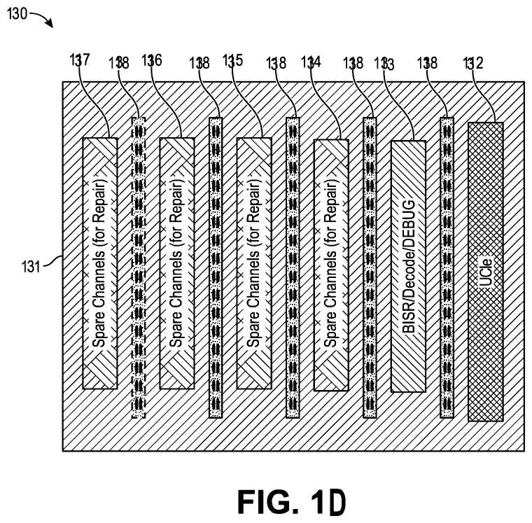

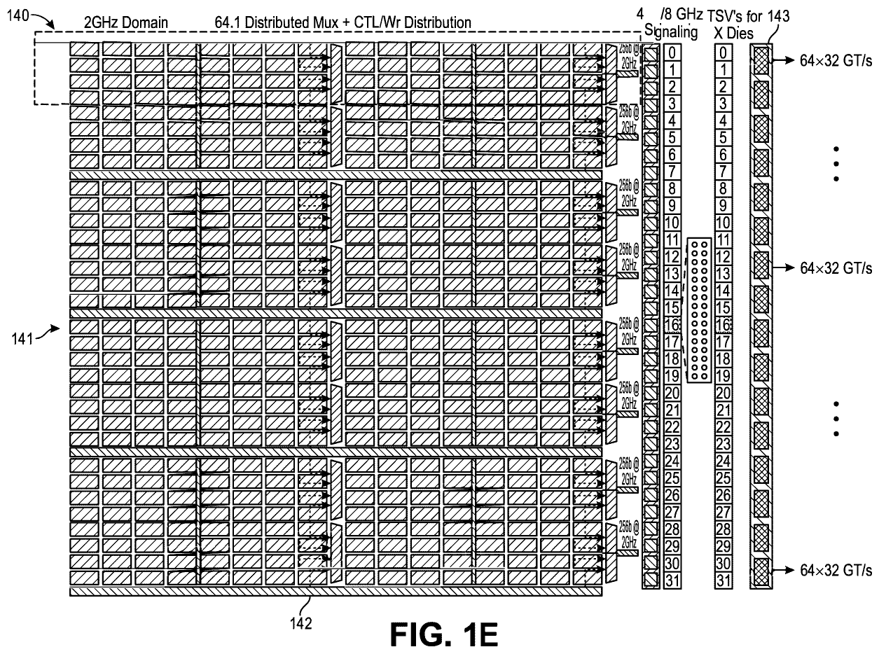

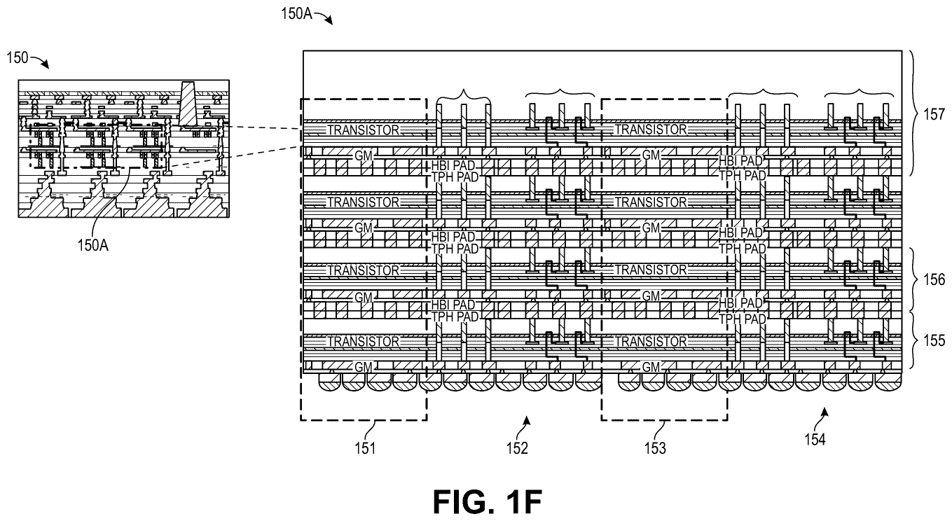

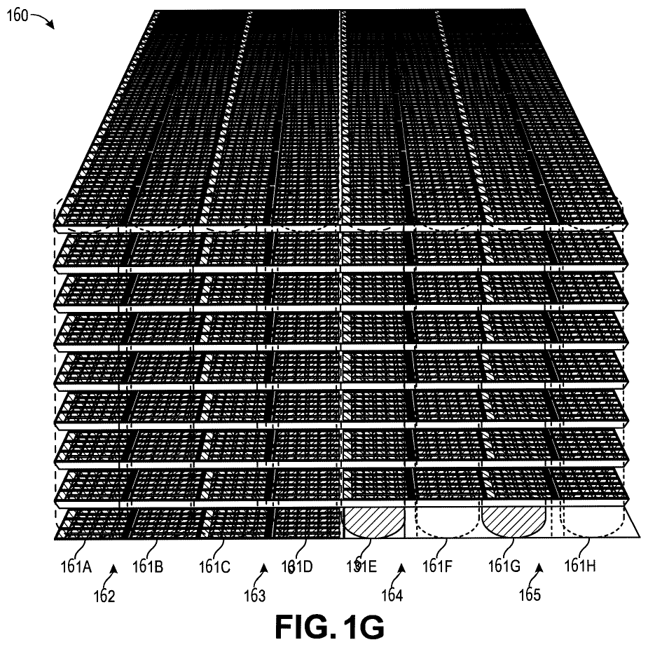

As an exemplary system including a high bandwidth memory, FIG. 1A illustrates a cross-sectional view of a package including a high bandwidth memory (HBM), in accordance with an embodiment of the present disclosure.

Referring to FIG. 1A, a package 100 includes a package substrate 101, an interposer 102 coupled to a top of the package substrate 101, and interconnect structures 103 are coupled to a bottom of the package substrate 101. A high bandwidth memory (HBM) stack 104 is coupled to the interposer 102. The HBM stack 104 includes like memory dies 105 and may include a bottom die different than the like memory dies 105 (base die), or may not include such a base die. A logic die 106 is also coupled to the interposer 102.

In accordance with an embodiment of the present disclosure, a die stacking cube is 8-high and beyond. In an embodiment, die stacking is achieved wafer-to-wafer. In another embodiment, die stacking is achieved die-to-die. In either case, die thinning may be used.

As an exemplary stack, FIG. 1B illustrates an angled view of a high bandwidth memory (HBM) die stack, in accordance with an embodiment of the present disclosure.

Referring to FIG. 1B, a memory structure 110 includes a stack 111 of dies 112. The dies have aligned databases (DBs) 113 and through silicon vias (TSVs) 114. In one embodiment, a base die 115 is included as a bottom die of the stack. In other embodiments, the base die 115 is omitted, and the bottom die in the stack 111 is the same as the upper dies 112.

As a first exemplary die option, FIGS. 1C and 1D illustrate plan views of a memory die 120 and base die 130 for a high bandwidth memory (HBM) die stack, in accordance with an embodiment of the present disclosure.

Referring to FIG. 1C, the memory die 120 has a span 121 of about 9.5 mm by a span 122 of about 13.5 mm. A stack of such dies can be stacked in a front to back (F2B) arrangement based on TSVs and HBIs. Domains 123, such as 2 GHz domains, are separated by CP slice locations 124, 125 and 126. Each such die 120 can be an approximately 1.5 GB die based on back-end-of-line transistors. Referring to FIG. 1D, the base die 130 includes a substrate 131 having a Universal Chiplet Interconnect Express (UCIe) 132, test/controller/debug region 133, regions 134, 135, 136 and 137 of spare channels for repair, and TSV regions 138. In one embodiment, the base die 130 includes a direct access debug mechanism, and/or redundancy for post-assembly repair.

As a second exemplary die option, FIG. 1E illustrates a plan view of a memory die for a high bandwidth memory (HBM) die stack, in accordance with another embodiment of the present disclosure.

Referring to FIG. 1E, as an example, a memory die 140 has a span 141 of about 9.5 mm by a span 142 of 14.5-15 mm. A stack of such dies can be stacked in a front to back (F2B) arrangement based on TSVs and HBIs. An associated domain 143 can be a 32 GHz domain, for example. In an embodiment, no base die is included with a stack of such dies 140. Instead, redundancy and test and debug logic is distributed throughout the stack. In an embodiment, all such dies 140 have I/O circuitry, but only the bottom die has the I/O circuitry turned on.

As an exemplary die stack, FIG. 1F illustrates a cross-sectional view 150 of a die stack and an associated exploded view 150A, in accordance with an embodiment of the present disclosure.

Referring to FIG. 1F, a die stack includes a first thin film transistor database 151, a first region 152 of TSV/HBI connections, a second thin film transistor database 153, and a second region 154 of TSV/HBI connections. Shown are a first wafer or die 155, a second wafer or die 156, and an eighth wafer or ninth wafer 157 (depending on where or not a base die is included), with an abbreviation of wafers or dies 3 to 7 or 3 to 8 shown in between. In an embodiment, thinning of the silicon can be implemented to enable many-layer stacking.

As an exemplary building block, FIG. 1G is a schematic of a basic building block for ultra high bandwidth memory, in accordance with an embodiment of the present disclosure.

Referring to FIG. 1G, a basic memory building block 160 includes sub-channel 0 161A, sub-channel 1 161B, sub-channel 2 161C, sub-channel 3 161D, sub-channel 4 161E, sub-channel 5 161F, sub-channel 6 161G, and sub-channel 7 161H. The basic memory building block 160 also includes a TSV gutter 0 162, a TSV gutter 1 163, a TSV gutter 2 164, and a TSV gutter 3 165.

Referring again to FIG. 1G, in accordance with an exemplary embodiment of the present disclosure, a basic memory building block of cross-batch memory (XBM) is an DRAM memory array designed as “datablock”, and the basic I/O building block is a UCIe I/O bundle hard operating at 32 GT/s. With the goal of matching HBM4's footprint, each XBM memory die is architected with “N” datablocks to have a die capacity of 0.5-5 GB. All I/O to the compute die is routed through a base die. The XBM stack is organized as “k” (e.g., 8) independent channels, each of which has “p” (e.g., 8) independent sub-channels. Each of the “sub-channels” is independently controllable by the processor (GPU/XPU/etc.), similar to the channels in HBM. Read/Write data (1-640 B block size) and control for each channel interface is through UCIe I/O bundles. Each sub-channel has 12 Datablocks (DB) in each die of the stack—up to 96 DB's for 8-high XBM (or 192 DB's for 16-high) per sub-channel. The channels operate at 2 GHz and are fully synchronous. The UCIe I/O operates at 32 GHz and serializes/deserializes data and control between the memory dies and compute die. Though UCIe I/O is unidirectional, in one embodiment, it is assumed that the bus is “logically bidirectional” and in a given cycle be doing either write or read. There are four TSV gutters in each die, one carrying data and control for sub-channels 0-1, and another for sub-channels 2-3 and so on. The base die has 4 die-sub-channels of redundant memory arrays (32 datablocks) to act as fungible recoverability resources for unrepairable defects in the top memory dies.

As exemplary channel organization, FIG. 1H is a schematic of channel organization for ultra high bandwidth memory, in accordance with an embodiment of the present disclosure.

Referring to FIG. 1H, a channel layout 170 for a die includes domains of sub-channels or regions 171 arranged along a channel 0 172, a channel 1 173, a channel 2 174, a channel 3 175, a channel 4 176, a channel 5 177, a channel 6 178, and a channel 7 179.

Referring again to FIG. 1H, in accordance with an exemplary embodiment of the present disclosure, each die has 768 datablocks arranged in 32 rows×24 columns. Physically, each 4-row block of all the stacked memory dies correspond to a channel and within that channel, each triplet of columns forms a sub-channel. Two sets of data and control buses from two sub-channels are sent through signal TSV's to the die below it. If it is read data, the data goes on to get muxed with the read data in the die below. If it is write data or command, the data are repeated to die above and distributed to the data blocks to the left and right, similar to the read data but in opposite directions. Charge pumps and clock trees are not depicted but can be included. In one embodiment, all pipe/staging flops for data and control is placed in the base die near the TSV gutters, and then the data is distributed through the TSV gutters and to the three datablocks to the left and three to the right of the gutters. The eight sub-channels within each channel share clock, strobes and a few miscellaneous control path signals.

It is to be appreciated that high bandwidth approaches and structures described above can be implemented in a variety of package options. An example is described in association with FIG. 1A. Other examples are described below.

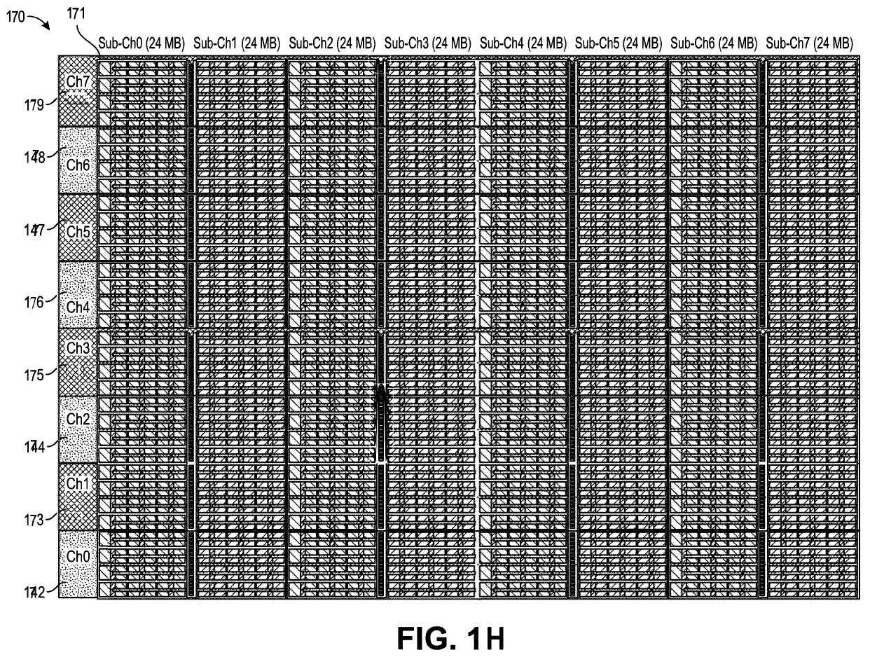

In another aspect, memory on package (MoP) architectures may be implemented for high bandwidth, high capacity memories such as described above. As an example, FIG. 2 is a cross-sectional illustration of an electronic package 200, in accordance with an embodiment of the present disclosure. The electronic package 200 includes an architecture where memory die stacks 220 are attached to a package substrate 205 adjacent to a die module 230. The package substrate 205 may include bumps 206 on a backside of the package substrate 205. The memory die stacks 220 and the die module 230 may be provided on the front side of the package substrate 205. For example, the memory die stack 220 may include bumps 226 that connect to the package substrate 205, and the die module 230 may include bumps 236 that connect to the package substrate 205. An underfill 237 may be provided around the bumps 236. While not shown, an underfill may also surround the bumps 226 between the memory die stack 220 and the package substrate 205.

In an embodiment, a mold layer 225 may be provided over and around the memory die stacks 220. The mold layer 225 may be an epoxy molding material or any other suitable material. In an embodiment, a thickness of the mold layer 225 may be greater than a height of the memory die stacks 220.

The die module 230 may include any number of dies 231 in any architecture. For example, a pair of dies 231 may be coupled to each other through a bridge 232 embedded in an interposer 235. The die module 230 may be a system on a chip (SoC) or any other type of die or dies. The die module 230 may be communicatively coupled to the memory die stacks 220 through routing (not shown) on and/or in the package substrate 205.

The memory die stacks 220 may include a memory package substrate 221. A stack of memory dies 222 may be provided over the memory package substrate 221. The memory dies 222 may be electrically coupled to the memory package substrate 221. A stiffener 211 may also be includes in order to mitigate warpage issues.

In another embodiment, MoP architectures that have a smaller Z-height and reduced X-Y form factor are described below.

In particular, a package substrate is provided and memory die stacks are provided directly on the package substrate. The memory dies may be directly coupled to the package substrate. As such, there is no need for a memory package substrate between the memory dies and the main package substrate. This results in a decrease in the Z-height of the device. Additionally, the X-Y form factor is reduced by the use of mold layer around the memory die stacks. The mold layer allows for the elimination of the stiffener in some embodiments. That is, the mold layer improves the stiffness of the package substrate, and there may not be a need for a stiffener. However, in other embodiments, a stiffener may also be included. In such an embodiment, the stiffener may also be embedded in the mold layer.

Memory on package (MoP) architectures have been used in order achieve the best DDR performance and smallest SoC XY footprint. However, there are a few intrinsic issues that arise with existing MoP architectures. One issue is an increased Z-height. The addition of a tall memory package (e.g., a stack of memory dies on a memory package substrate) increases the Z-height of the device. For example, Z-heights may be increased by between 300 μm and 350 μm in some architectures. In some instances, the increase in the Z-height is mitigated by using a coreless package architecture. However, the use of a coreless architecture can be an extremely expensive solution.

Additionally, the MoP architecture can result in an overall SoC package XY form factor that is substantially large. This is due to the need to include a stiffener in order to control warpage of the package substrate. In some instances, a combination stiffener and integrated heat spreader (IHS) is used in order to control warpage and improve thermal performance. However, such architectures are expensive solutions.

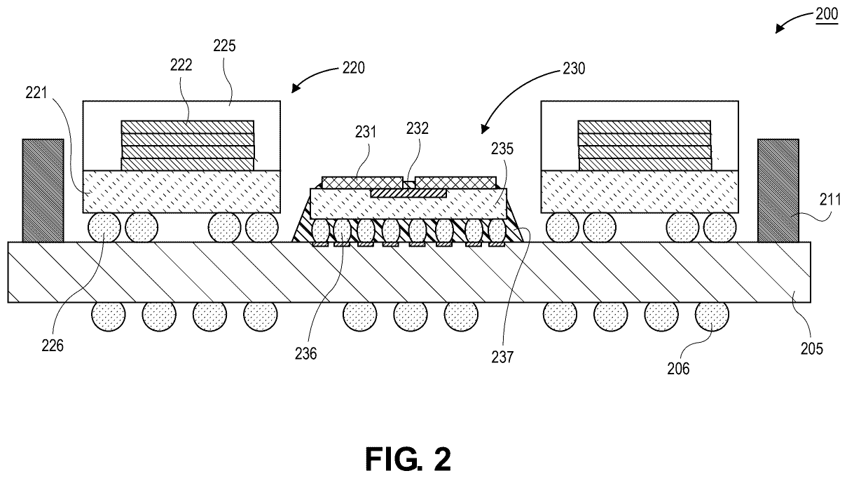

Referring now to FIG. 3, a plan view illustration of an electronic package 300 is shown, in accordance with an embodiment of the present disclosure. The electronic package 300 may include a package substrate 305. The package substrate 305 may include a core and buildup layers over and under the core. Depending on the routing needs, the package substrate 305 may be a six layer package substrate 305, an eight layer package substrate 305, or a ten layer package substrate 305. It is to be appreciated that embodiments disclosed herein may include package substrates 305 with any number of routing layers. Since a core is used, the cost of the package substrate 305 is reduced and the stiffness is increased (compared to coreless architectures).

In an embodiment, a mold layer 328 may be provided over a top surface of the package substrate 305. The mold layer 328 may be an epoxy molding material or any other suitable material. In an embodiment, the mold layer 328 is an electrically insulating material. In an embodiment, the mold layer 328 has an outer perimeter that is smaller than an outer perimeter of the package substrate 305. However, the outer perimeter of the mold layer 328 may be substantially equal to the outer perimeter of the package substrate 305 in other embodiments. In an embodiment, the mold layer 328 may have an opening 329. The opening 329 may be sized to receive a die module 330. While shown as a single die in FIG. 3, it is to be appreciated that the die module 330 may include one or more dies. The die module 330 may also include an interposer for coupling multiple dies together.

In an embodiment, a plurality of memory die stacks 320 may be embedded in the mold layer 328. For example, the die stacks 320 in FIG. 3 are shown with dashed lines in order to illustrate that the memory die stacks 320 are provided below the top surface of the mold layer 328. The memory die stacks 320 may be directly coupled to the package substrate 305. That is, the memory die stacks 320 may not need a memory package substrate between the memory dies and the package substrate 305, as is the case in the example shown in FIG. 2. This reduces the Z-height of the electronic package 300. Additionally, the omission of the memory package substrate can reduce the length of the routing between the die module 330 and the memory die stack 320. In the illustrated embodiment, there are four memory die stacks 320. However, it is to be appreciated that any number of memory die stacks 320 may be used in accordance with various embodiments. For example, there may be one or more memory die stacks 320 in the electronic package 300.

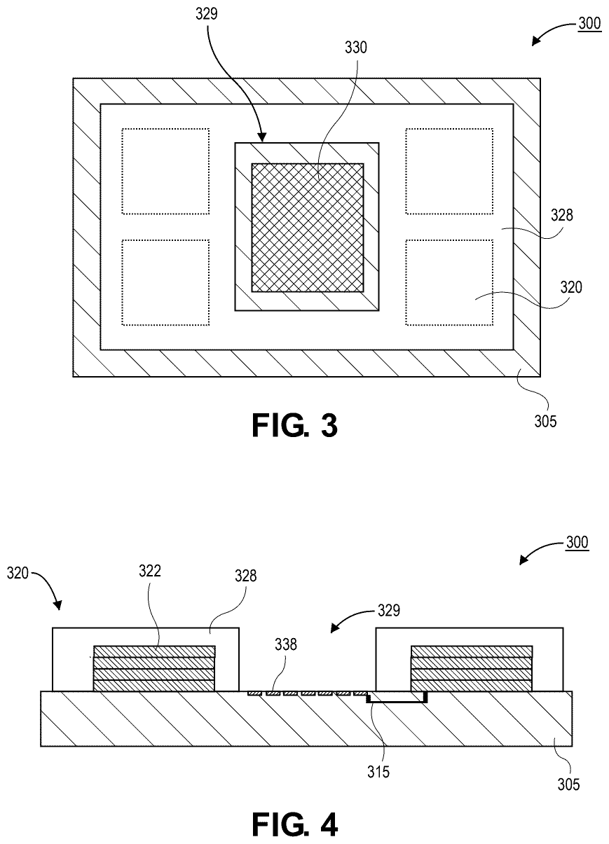

Referring now to FIG. 4, a cross-sectional illustration of an electronic package 300 is shown, in accordance with an embodiment. As shown, the memory die stacks 320 are directly coupled to the package substrate 305. That is, a bottommost memory die 322 is directly contacting the package substrate 305. In an embodiment, the memory dies 322 may be electrically coupled to one another by TSVs and then to underlying to pads (not shown) on the package substrate 305. As used herein, a memory die stack 320 may refer to a stack of one or more memory dies 322. In a particular embodiment, four memory dies 322 are included in the memory die stack 320, as is depicted. In other embodiment, 8 or more dies are included, such as described in the examples above.

The memory die stacks 320 may be embedded in a mold layer 328. The mold layer 328 may be around sidewalls and top surfaces of the memory dies 322. In the illustrated embodiment, the mold layer 328 appears as two separate regions (one region around each of the memory die stacks 320). However, it is to be appreciated that the two separate regions may be coupled together by portions of the mold layer 328 that are provided outside of the plane of FIG. 4.

An opening 329 may be provided through the mold layer 328. The opening 329 may be provided in the middle of the mold layer 328 in order to accommodate the die module (not shown in FIG. 4). In an embodiment, pads 338 may be provided in the opening 329. The die module may be connected to the package substrate 305 through the pads 338. In an embodiment, certain ones of the pads 338 may be coupled to the memory die stack 320 by routing 315 in and/or on the package substrate 305.

It is to be appreciated that although the structures of FIGS. 3 and 4 provide improvements over the structure of FIG. 2, other approaches and architectures can be implemented to provide improvements over the structure of FIG. 2. In another aspect, in accordance with embodiments of the present disclosure, a dynamic random access memory (DRAM) package is reversely mounted to a system on chip (SOC) package through an extended DRAM substrate. In one embodiment, the DRAM substrate is connected to the SOC package through a copper plated through hole aligning to a pre-solder on the SOC package. In an embodiment, Package Z height can be further reduced by eliminating the DRAM solder ball. In an embodiment, a copper pillar is formed at the DRAM to allow DRAM power direct feed from a voltage regulator (VR)/power management integrated circuit (VR/PMIC).

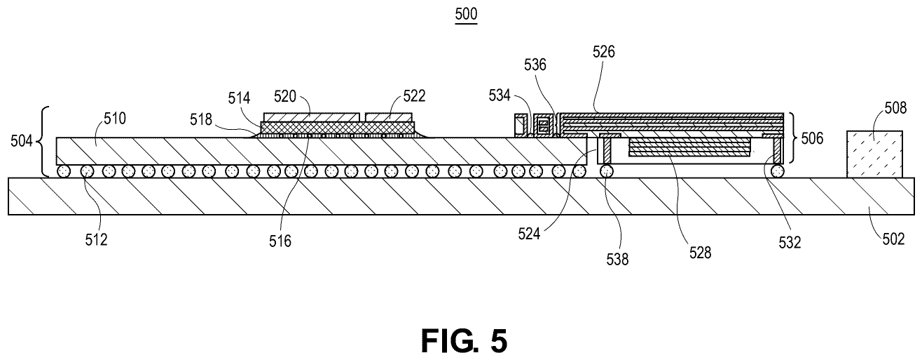

As an example, FIG. 5 illustrates a cross-sectional view of a system including a reversed overhang memory on package structure, in accordance with an embodiment of the present disclosure.

Referring to FIG. 5, a system 500 includes a board 502, such as a mother board. A reversed overhang memory on package structure 504 is coupled to the board 502. The reversed overhang memory on package structure 504 includes a memory stack 506, such as a DRAM memory stack. The system 500 can also include a voltage regulator (VR) 508 coupled to the board 502, which can be coupled to the memory stack 506. The reversed overhang memory on package structure 504 also includes a package substrate 510, which may include layers of traces and vias therein. The package substrate 510 can be electrically coupled to the board 502 by conductive bumps and/or solder balls 512. A die 514, such as a processor die or memory die or base die, can be coupled to the package substrate 510, e.g., by conductive bumps and/or solder balls 516 which can be surrounded by an underfill layer 518. Additional dies 520 and 522, such as processor dies or memory dies, can be coupled to the die 514. The memory stack 506 includes a die stack structure 524 coupled to a substrate 526, such as a DRAM substrate. The die stack structure 524 can include a stack of dies 528, such as DRAM dies, together with through vias 532, e.g., all in a mold layer. The substrate 526 can be coupled to the package substrate 510 using pre-solder 534 and plated through holes 536. The memory stack 506 can be electrically coupled to the board 502 by conductive bumps and/or solder balls 538. In an embodiment, the substrate 526 extends laterally beyond the package substrate 510, and the die stack structure 524 of the memory stack 506 is laterally spaced apart from the package substrate 510. The resulting architecture can be referred to as an overhang structure. It is to be appreciate that although only one overhang memory stack 506 is depicted, additional overhang memory stacks can be included as arranged around die 514, e.g., in a layout such as described in association with FIGS. 3 and 4.

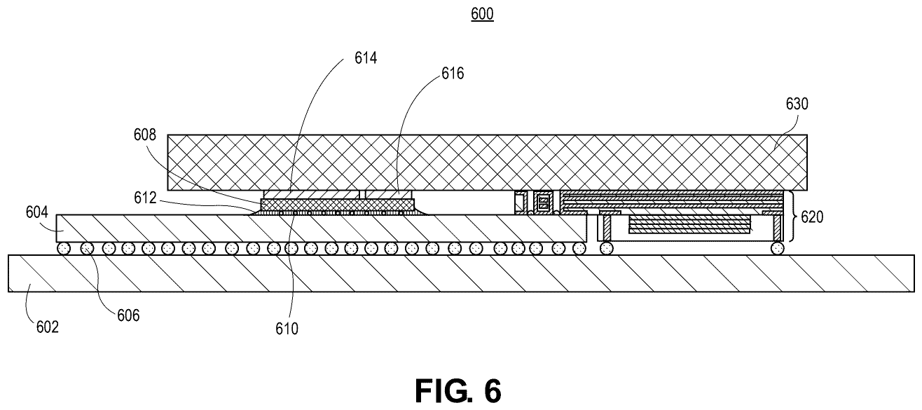

Embodiments may enable the use of a flat heat spreader. As an example, FIG. 6 illustrates a cross-sectional view of a system including a reversed overhang memory on package structure, in accordance with an embodiment of the present disclosure.

Referring to FIG. 6, a system 600 includes a board 602, such as a mother board. A reversed overhang memory on package structure is coupled to the board 602. The reversed overhang memory on package structure includes a memory stack 620, such as a DRAM memory stack. The reversed overhang memory on package structure also includes a package substrate 604, which may include layers of traces and vias therein. The package substrate 604 can be electrically coupled to the board 602 by conductive bumps and/or solder balls 606. A die 608, such as a processor die or memory die or base die, can be coupled to the package substrate 604, e.g., by conductive bumps and/or solder balls 610 which can be surrounded by an underfill layer 612. Additional dies 614 and 616, such as processor dies or memory dies, can be coupled to the die 608. The memory stack 620 can include a die stack structure coupled to a substrate, such as a DRAM substrate. The die stack structure can include a stack of dies, such as DRAM dies, together with through vias, e.g., all in a mold layer. The substrate of the memory stack 620 can be coupled to the package substrate 604 using pre-solder and plated through holes. The memory stack 620 can be electrically coupled to the board 602 by conductive bumps and/or solder balls. A heat spreader or heat sink 630, such as a copper slug or dummy silicon die, can be included and, in one embodiment, can have a flat interface with the underlying structure, as is depicted. It is to be appreciate that although only one overhang memory stack 620 is depicted, additional overhang memory stacks can be included as arranged around die 608, e.g., in a layout such as described in association with FIGS. 3 and 4.

It is to be appreciated that embodiments described herein can be implemented to achieve low power and improve power delivery efficiency with direct power feed/shorter path from VR/PMIC.

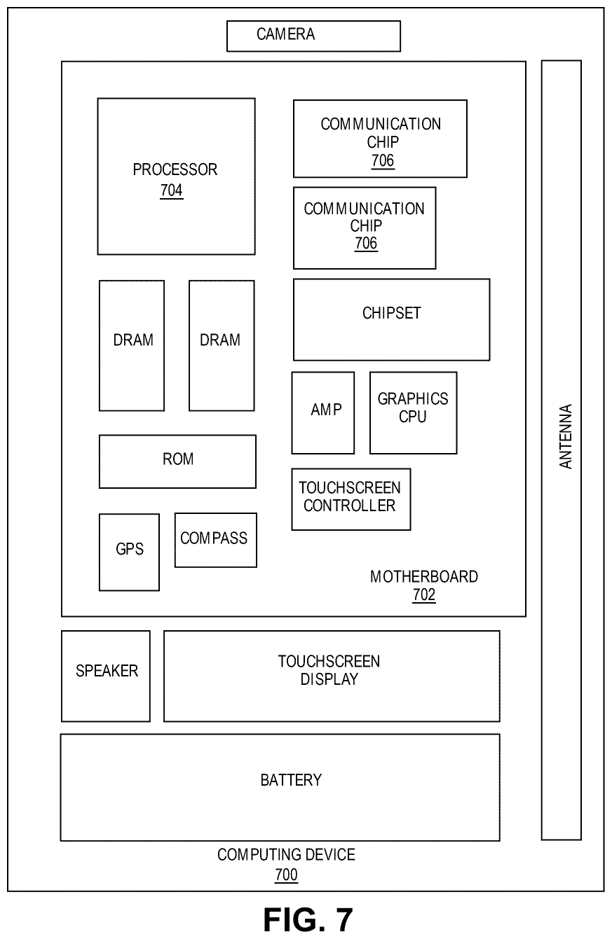

FIG. 7 illustrates a computing device 700 in accordance with one implementation of the disclosure. The computing device 700 houses a board 702. The board 702 may include a number of components, including but not limited to a processor 704 and at least one communication chip 706. The processor 704 is physically and electrically coupled to the board 702. In some implementations the at least one communication chip 706 is also physically and electrically coupled to the board 702. In further implementations, the communication chip 706 is part of the processor 704.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 706 enables wireless communications for the transfer of data to and from the computing device 700. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 706 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 700 may include a plurality of communication chips 706. For instance, a first communication chip 706 may be dedicated to shorter range wireless communications such as Wi-Fi and Bluetooth and a second communication chip 706 may be dedicated to longer range wireless communications such as GPS, EDGE, GPRS, CDMA, WiMAX, LTE, Ev-DO, and others.

The processor 704 of the computing device 700 includes an integrated circuit die packaged within the processor 704. In some implementations of the disclosure, the integrated circuit die of the processor may be part of an electronic system that includes one or more high bandwidth memory structures, in accordance with embodiments described herein. The term “processor” may refer to any device or portion of a device that processes electronic data from registers and/or memory to transform that electronic data into other electronic data that may be stored in registers and/or memory.

The communication chip 706 also includes an integrated circuit die packaged within the communication chip 706. In accordance with another implementation of the disclosure, the integrated circuit die of the communication chip may be part of an electronic system that includes one or more high bandwidth memory structures, in accordance with embodiments described herein.

Thus, embodiments of the present disclosure include ultra high bandwidth memory (HBM) with backend transistors, and methods of fabricating ultra high bandwidth memory (HBM) with backend transistors.

The above description of illustrated implementations of embodiments of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description. The terms used in the following claims should not be construed to limit the disclosure to the specific implementations disclosed in the specification and the claims.

Although specific embodiments have been described above, these embodiments are not intended to limit the scope of the present disclosure, even where only a single embodiment is described with respect to a particular feature. Examples of features provided in the disclosure are intended to be illustrative rather than restrictive unless stated otherwise. The above description is intended to cover such alternatives, modifications, and equivalents as would be apparent to a person skilled in the art having the benefit of the present disclosure.

The scope of the present disclosure includes any feature or combination of features disclosed herein (either explicitly or implicitly), or any generalization thereof, whether or not it mitigates any or all of the problems addressed herein. Accordingly, new claims may be formulated during prosecution of the present application (or an application claiming priority thereto) to any such combination of features. In particular, with reference to the appended claims, features from dependent claims may be combined with those of the independent claims and features from respective independent claims may be combined in any appropriate manner and not merely in the specific combinations enumerated in the appended claims.

Various embodiments or aspects of the disclosure are described herein. In some implementations, the different embodiments are practiced separately. However, embodiments are not limited to embodiments being practiced in isolation. For example, two or more different embodiments can be combined together in order to be practiced as a single device, process, structure, or the like. The entirety of various embodiments can be combined together in some instances. In other instances, portions of a first embodiment can be combined with portions of one or more different embodiments. For example, a portion of a first embodiment can be combined with a portion of a second embodiment, or a portion of a first embodiment can be combined with a portion of a second embodiment and a portion of a third embodiment. The following examples pertain to further embodiments. The various features of the different embodiments may be variously combined with some features included and others excluded to suit a variety of different applications.

Example embodiment 1: A memory structure includes a package substrate. A base die is coupled to the package substrate. A memory die stack is coupled to the base die. Each memory die in the die stack includes one transistor one capacitor (1T1C) backend dynamic random access memory (DRAM).

Example embodiment 2: The memory structure of example embodiment 1, wherein the memory die stack includes eight memory dies.

Example embodiment 3: The memory structure of example embodiment 1 or 2, wherein each memory die in the die stack includes a built-in self-test (BIST).

Example embodiment 4: The memory structure of example embodiment 1, 2 or 3, wherein each memory die in the die stack includes redundancy.

Example embodiment 5: The memory structure of example embodiment 1, 2, 3 or 4, wherein each memory die in the die stack includes a plurality of alternating sub-channels and through-silicon via (TSV) gutters.

Example embodiment 6: A memory structure includes a package substrate. A memory die stack is coupled to the package substrate. Each memory die in the die stack includes one transistor one capacitor (1T1C) backend dynamic random access memory (DRAM).

Example embodiment 7: The memory structure of example embodiment 6, wherein the memory die stack includes eight memory dies.

Example embodiment 8: The memory structure of example embodiment 6 or 7, wherein each memory die in the die stack includes a built-in self-test (BIST).

Example embodiment 9: The memory structure of example embodiment 6, 7 or 8, wherein each memory die in the die stack includes redundancy.

Example embodiment 10: The memory structure of example embodiment 6, 7, 8 or 9, wherein each memory die in the die stack includes a plurality of alternating sub-channels and through-silicon via (TSV) gutters.

Example embodiment 11: A computing device includes a board, and a memory structure coupled to the board. The memory structure includes a package substrate. A base die is coupled to the package substrate and a memory die stack is coupled to the base die, or a memory die stack is coupled to the package substrate. Each memory die in the die stack includes one transistor one capacitor (1T1C) backend dynamic random access memory (DRAM).

Example embodiment 12: The computing device of example embodiment 11, including the base die coupled to the package substrate and the memory die stack coupled to the base die.

Example embodiment 13: The computing device of example embodiment 11, including the memory die stack coupled to the package substrate.

Example embodiment 14: The computing device of example embodiment 11, 12 or 13, further including a processor coupled to the board.

Example embodiment 15: The computing device of example embodiment 11, 12, 13 or 14, further including a communication chip coupled to the board.

Example embodiment 16: The computing device of example embodiment 11, 12, 13, 14 or 15, further including a battery coupled to the board.

Example embodiment 17: The computing device of example embodiment 11, 12, 13, 14, 15 or 16, further including a camera coupled to the board.

Example embodiment 18: The computing device of example embodiment 11, 12, 13, 14, 15, 16 or 17, further including a display coupled to the board.

Example embodiment 19: The computing device of example embodiment 11, 12, 13, 14, 15, 16, 17 or 18, further including a compass coupled to the board.

Example embodiment 20: The computing device of example embodiment 11, 12, 13, 14, 15, 16, 17, 18 or 19, further including a GPS coupled to the board.

What is claimed is:

1. A memory structure, comprising:
a package substrate;
a base die coupled to the package substrate; and
a memory die stack coupled to the base die, wherein each memory die in the die stack comprises one transistor one capacitor (1T1C) backend dynamic random access memory (DRAM).

2. The memory structure of claim 1, wherein the memory die stack comprises eight memory dies.

3. The memory structure of claim 1, wherein each memory die in the die stack comprises a built-in self-test (BIST).

4. The memory structure of claim 1, wherein each memory die in the die stack comprises redundancy.

5. The memory structure of claim 1, wherein each memory die in the die stack comprises a plurality of alternating sub-channels and through-silicon via (TSV) gutters.

6. A memory structure, comprising:
a package substrate; and
a memory die stack coupled to the package substrate, wherein each memory die in the die stack comprises one transistor one capacitor (1T1C) backend dynamic random access memory (DRAM).

7. The memory structure of claim 6, wherein the memory die stack comprises eight memory dies.

8. The memory structure of claim 6, wherein each memory die in the die stack comprises a built-in self-test (BIST).

9. The memory structure of claim 6, wherein each memory die in the die stack comprises redundancy.

10. The memory structure of claim 6, wherein each memory die in the die stack comprises a plurality of alternating sub-channels and through-silicon via (TSV) gutters.

11. A computing device, comprising:
a board; and
a memory structure coupled to the board, the memory structure comprising:
a package substrate; and
a base die coupled to the package substrate and a memory die stack coupled to the base die, or a memory die stack coupled to the package substrate,
wherein each memory die in the die stack comprises one transistor one capacitor (1T1C) backend dynamic random access memory (DRAM).

12. The computing device of claim 11, comprising the base die coupled to the package substrate and the memory die stack coupled to the base die.

13. The computing device of claim 11, comprising the memory die stack coupled to the package substrate.

14. The computing device of claim 11, further comprising:
a processor coupled to the board.

15. The computing device of claim 11, further comprising:
a communication chip coupled to the board.

16. The computing device of claim 11, further comprising:
a battery coupled to the board.

17. The computing device of claim 11, further comprising:
a camera coupled to the board.

18. The computing device of claim 11, further comprising:
a display coupled to the board.

19. The computing device of claim 11, further comprising:
a compass coupled to the board.

20. The computing device of claim 11, further comprising:
a GPS coupled to the board.
